(19) United States
(12) Patent Application Publication
(10) Pub. No.: US 2025/0307498 A1
(43) Pub. Date: Oct. 2, 2025

(54) DESIGN GENERATION DEVICE AND DESIGN GENERATION METHOD

(71) Applicant: AXION Co., Ltd., Seongnam-si (KR)

(72) Inventors: Kee Sup KIM, El Dorado Hills, CA (US); Younggwang JUNG, Incheon (KR); Eun Taek OH, Seoul (KR)

(21) Appl. No.: 19/075,489

(22) Filed: Mar. 10, 2025

Related U.S. Application Data
(60) Provisional application No. 63/563,377, filed on Mar. 10, 2024.

(51) Int. Cl. G06F 30/27

(52) U.S. Cl. CPC G06F 30/27

(57) ABSTRACT

The present disclosure relates to a design generation device including a design generator configured to generate at least one design from design data when design data is input, a simulator configured to simulate the at least one design and evaluate a result of the simulating, and an optimization engine configured to derive an optimization parameter for the at least one design by inputting the evaluation result obtained from the simulator into a parameter optimization model provided in advance, wherein the design generator modifies the at least one design according to the optimization parameter. By doing so, an optimized design may be automatically generated by reflecting industry-specific characteristics and user needs.

### CROSS-REFERENCE TO RELATED APPLICATION(S)

This application claims priority under 35 USC 119 to U.S. Provisional Application No. 63/563,377, filed on Mar. 10, 2024, the contents of which is incorporated herein by reference in its entirety.

### FIELD OF THE DISCLOSURE

The present disclosure relates to a design generation device and a design generation method capable of generating a design for each industrial field.

### BACKGROUND OF THE RELATED ART

Digital simulation technology has long been used to evaluate product and system designs. Traditionally, the digital simulation technology has been widely used in fields of semiconductor designs, an automotive industry, aerospace, etc., and has achieved development cost reduction and performance optimization.

Recently, with advancements in digital twin and high-performance computer simulation technologies, various industries that previously did not actively utilize simulation are adopting these technologies. For example, financial institutions use market simulators to predict stock price movements and analyze risks under various economic scenarios, while an aerospace industry uses fluid dynamics simulations to evaluate and optimize efficiency of wing designs.

As such, use of computer-based simulation technology is increasing in various industries, and development of simulation techniques capable of precise analysis and prediction is needed. Accordingly, new simulation and optimization methods are needed to meet such technical requirements.

### SUMMARY OF THE DISCLOSURE

### Technical Problems

The present disclosure has been made to solve the above problems, and an object of the present disclosure is to provide a design generation device and a design generation method capable of automatically generating an optimized design by reflecting industry-specific characteristics and user needs.

### Technical Solution

To accomplish the above-mentioned objects, according to one aspect of the present disclosure, there is provided a design generation device including: a design generator configured to generate at least one design from design data; a simulator configured to simulate the generated at least one design; and an optimization engine configured to derive an optimization parameter for the generated at least one design by inputting a simulation result obtained from the simulator into pre-provided parameter optimization model, wherein the design generator modifies the generated at least one design according to the derived optimization parameter.

In addition, the simulator may include an early-stage estimator configured to estimate a final simulation result from a preliminary simulation result obtained from the simulator with respect to the at least one design to establish preliminary design optimization.

In addition, the early-stage estimator may include a prediction model trained to estimate the final simulation result using the simulation result as learning data.

In addition, the early-stage estimator may identify a design area covered by the learning data by inputting the learning data into a pre-provided coverage check model, and train the prediction model by augmenting the learning data to secure learning data for a new design sub-space according to the identified design area.

In addition, the optimization engine may evaluate whether the final simulation result estimated by the early-stage estimator satisfies a target value corresponding to a predefined optimization objective, and when the target value is not satisfied, repeatedly perform a process of deriving and transmitting a new optimization parameter to the design generator until the target value is satisfied.

In addition, the optimization engine may include: a feature extractor configured to extract a key feature from the simulation result according to an optimization objective and preprocess the extracted key feature; and an optimizer configured to input the preprocessed key feature into the at least one parameter optimization model to derive an optimization parameter.

In addition, the optimization engine may further include an optimization model selector configured to select the at least one parameter optimization model configured to derive the optimization parameter according to the optimization objective and the key feature extracted from the feature extractor.

In addition, the optimization engine may generate a domain-adaptive parameter optimization model by performing transfer learning through determination of a similarity between design domains for the at least one parameter optimization model provided in advance.

In addition, when a predefined optimization objective includes multiple optimization objectives (multi-objectives) including at least two optimization objectives, the optimization engine may find an optimization point that satisfies the multiple optimization objectives and derive the optimization parameter by reflecting an importance weight for each of the multiple optimization objectives according to the optimization point.

In addition, the optimization engine may derive optimization parameters for a plurality of designs based on parallel processing, determines priorities for the plurality of designs based on the optimization parameters for the plurality of designs, respectively, and dynamically allocate resources for deriving the optimization parameters according to the priorities.

In addition, the optimization engine may train the at least one parameter optimization model based on learning data of a human design generated by an expert to pursue parameters of the human design.

To accomplish the above-mentioned objects, according to one aspect of the present disclosure, there is provided a design generation method including: generating, by a design generator, at least one design when design data is input; simulating, by a simulator, the generated at least one design; deriving, by an optimization engine, an optimization parameter for the generated at least one design by inputting a simulation result obtained from the simulator into a parameter optimization model provided in advance; and modifying, by the design generator, the generated at least one design according to the derived optimization parameter.

In addition, the simulating may include estimating, by an early-stage estimator, a final simulation result from a preliminary simulation result with respect to the generated at least one design to establish a preliminary design optimization.

In addition, the early-stage estimator may include a prediction model trained to predict the final simulation result using the simulation result as learning data.

In addition, the deriving of the optimization parameter may include: evaluating whether the final simulation result estimated by the early-stage estimator satisfies a target value corresponding to a predefined optimization objective, and when the target value is not satisfied, repeatedly performing a process of deriving and transmitting a new optimization parameter to the design generator until the target value is satisfied.

### Advantageous Effects

According to one aspect of the present disclosure described above, a design generation device and a design generation method are provided to automatically generate an optimized design by reflecting industry-specific characteristics and user needs.

### BRIEF DESCRIPTION OF THE DRAWINGS

The above and other objects, features and advantages of the present disclosure will be apparent from the following detailed description of the embodiments of the disclosure in conjunction with the accompanying drawings, in which:

FIG. 1 is a block diagram for explaining components of a design generation device according to an embodiment of the present disclosure;

FIG. 2 is a diagram for explaining an optimization engine according to an embodiment of the present disclosure;

FIG. 3 is a diagram illustrating an example of a case in which the design generation device according to an embodiment of the present disclosure generates a semiconductor chip design; and

FIG. 4 is a flowchart for explaining a design generation method according to an embodiment of the present disclosure.

### DETAILED DESCRIPTION OF THE PREFERRED EMBODIMENT

Features and advantages of the technical solution of the present disclosure and methods of accomplishing the same may be understood more readily with reference to the following detailed description of particular embodiments of the present disclosure and the accompanying drawings.

However, certain detailed explanations of well-known functions relevant to the present disclosure are omitted when it is deemed that they may unnecessarily obscure the essence of the present disclosure. It should be noted that like reference numerals in the drawings denote like elements.

Hereinafter, terms or words used in the description and drawings should not be interpreted as being limited to have a general meaning or a meaning defined in a dictionary, but should be interpreted as having a meaning and a concept which are consistent with the technical ideas of the present disclosure, based on a principle such that an inventor may properly define concepts of the terms to explain the disclosure of the inventor by using an optimum method. Accordingly, it should be understood that embodiments in the specifications and configurations illustrated in drawings are only example embodiments, and there is no intent to limit the example embodiments to the particular forms disclosed, but on the contrary, example embodiments are to cover all modifications, equivalents, and alternatives falling within the scope of the present disclosure.

Additionally, when an element is referred to as being “connected” or “coupled” to another element, this means that the element may be logically or physically connected or coupled to the another element. In other words, it should be understood that the element may be directly connected or coupled to the another element, but intervening elements may be present or the element may be indirectly connected or coupled to the another element.

In addition, the terms used in the present specification are merely used to describe particular embodiments, and are not intended to limit the present disclosure. A singular representation may include a plural representation unless it represents a definitely different meaning from the context.

In addition, it is to be understood that the terms such as “including” or “having,” etc. described herein are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

The term “module” used in various embodiments herein may include a unit implemented in hardware, software or firmware, and may be used interchangeably with terms such as logic, logic block, component, or circuit.

In this specification, each component according to various embodiments (e.g., a module or a program) may contain one or more entities, and some of the entities may be separated and placed in other components. According to various embodiments, one or more of the aforementioned components or operations may be omitted, or one or more other components or operations may be added. Alternatively or additionally, a plurality of components (e.g. (modules or programs) may be integrated into a single component. In this case, the component resulting from the integration may perform one or more functions of each of the plurality of components identically or similarly to those performed by a corresponding component among the plurality of components before the integration.

According to various embodiments, operations performed by a module, program or other component may be performed sequentially, in parallel, iteratively, or heuristically, or one or more of the operations may be performed in a different order, omitted, or one or more other operations may be added.

Hereinafter, embodiments of the present disclosure will be described in detail with reference to the accompanying drawings.

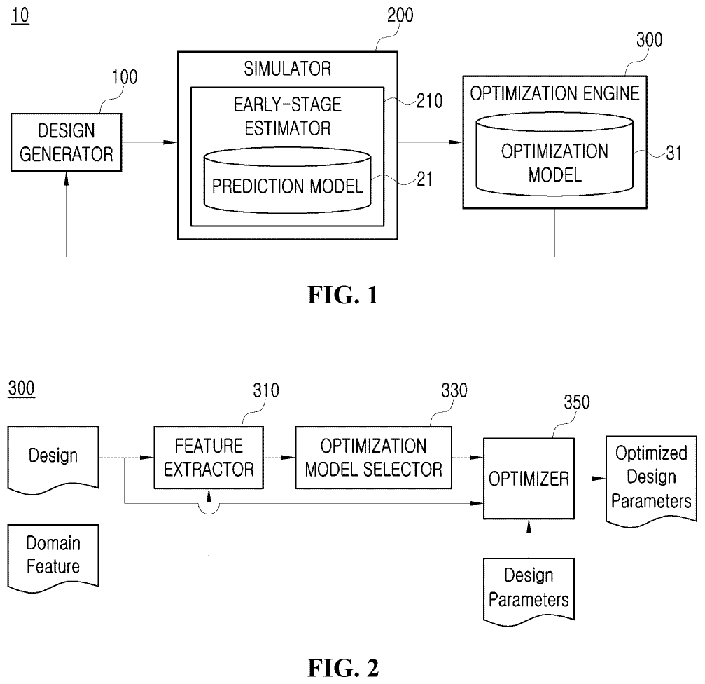

FIG. 1 is a block diagram for explaining components of a design generation device 10 according to an embodiment of the present disclosure. FIG. 2 is a diagram for explaining an optimization engine according to an embodiment of the present disclosure.

The design generation device 10 (hereinafter, referred to as a device) according to the present embodiment may be provided to automatically generate an optimized design by reflecting industry-specific characteristics and user needs, and automatically generate a design needed regardless of a technical field without being limited to a particular industry.

To do so, the device 10 according to the present embodiment may be configured to include a design generator 100, a simulator 200, and an optimization engine 300 including a parameter optimization model 31 provided in advance. In addition, software (an application) configured to perform a design generation method may be installed and executed in the device 10, and the design generator 100, the simulator 200, and the optimization engine 300 may be controlled by the software (the application) configured to perform a design generation method.

At this time, the device 10 may be a separate terminal or a partial module of a terminal. Additionally, components such as the design generator 100, simulator 200 and optimization engine 300 may be configured as an integrated module, or one or more modules. However, conversely, respective components may be configured as separate modules.

Additionally, the device 10 may have mobility or be fixed. The device 10 may have a form of a server or an engine, or be referred to as other terms such as a device, an apparatus, a terminal, a user equipment (UE), a mobile station (MS), a wireless device, a handheld device, etc. In addition, the device 10 may execute or produce various software based on an operating system (OS), that is, a system. Here, the operating system refers to a system program that allows software to use hardware of a device, and may include a mobile computer operating system such as an Android OS, iPhone operating system (iOS), a Windows mobile OS, a Bada OS, a Symbian OS, or a Blackberry OS, as well as a computer operating system such as Windows, Linux, Unix, Macintosh (MAC), advanced interactive executive (AIX), or Hewlett Packard Unix (HP-UX).

Hereinafter, a detailed configuration of the device 10 is described.

First, the design generator 100 may perform a function of generating one or more designs according to a predefined criterion based on design data input to generate a design.

At this time, the design data may be input by a user or prestored.

The design data may include basic data and design architecture data.

The basic data may include information about a technical field to which a design to be generated is to be applied, and regulatory and standard specification information.

The design architecture data may include high-level elements constituting a design, connection method information, and structural information that constitutes a foundation. For example, the design architecture data may mean connection structures of two legs, four legs, respective parts, or the like when the design generator 100 generates a robot design, the design architecture data may mean register transfer level (RTL)/system architecture, etc. when the design generator 100 generates a semiconductor design, or the design architecture data may mean a platform, a driving method, a powertrain, and a vehicle body structure, etc. when the design generator 100 generates a vehicle design.

Meanwhile, the design data described above is only an example, and it is obvious that any data needed for design generation may be included in the design data.

The design generator 100 according to the present embodiment may modify a generated design based on an optimization parameter derived from the optimization engine 300.

The design generator 100 according to the present embodiment may transmit the generated design or the modified design to the simulator 200 to simulate whether the generated design or the modified design meets a predefined optimization objective.

The simulator 200 is provided to simulate a design generated or modified by the design generator 100.

The simulator 200 may perform a multi-stage simulation on the generated design as shown in FIG. 1. That is, the simulator 200 may perform simulations sequentially or in parallel for each parameter.

Particularly, the simulator 200 according to the present embodiment may include an early-stage estimator 210, as shown in FIG. 1.

The early-stage estimator 210 according to the present embodiment estimates a final simulation result based on a preliminary simulation result of the design obtained from the simulator 200 to establish preliminary design optimization. In detail, the early-stage estimator 210 may estimate a final simulation result by preloading at least a partial result from the multi-stage simulation results by the simulator. The at least partial result may be a result obtained before the final simulation result is derived, among the multi-stage simulation results, or a simulation result in a preset early stage among the multi-stage simulation results.

To do so, the early-stage estimator 210 according to the present embodiment may include a prediction model 21 based on machine learning. The prediction model 21 may be a model trained to predict a final simulation result using a simulation result as learning data.

The early-stage estimator 210 according to the present embodiment may compare an actual final simulation result obtained from simulation by the simulator 200 to the estimated final simulation result, and update the prediction model 21 according to a result of the comparison.

The early-stage estimator 210 according to the present embodiment may augment learning data to secure learning data regarding various design areas. In detail, the early-stage estimator 210 may input current learning data into a pre-provided coverage check model (not shown) to check a design area covered by the learning data, and may augment the learning data to secure learning data regarding a new design sub-space according to the checked design area. That is, the early-stage estimator 210 may analyze a pattern of learning data to identify a design area in which an area covered by the learning data is lower than a preset threshold, and augment learning data using a design in a new design sub-space that is a different area from the identified design area.

To do so, the early-stage estimator 210 according to the present embodiment may generate learning data covering a new design sub-space from current learning data using a generative adversarial network (GAN). In detail, the early-stage estimator 210 may learn a distribution of the current learning data using a generative adversarial network (GAN) to generate a new set of design candidates, and then, select an optimal design from among the generated set of design candidates based on a Bayesian optimization technique and include the selected optimal design in the learning data to augment the learning data.

In addition, the early-stage estimator 210 according to the present embodiment may generate learning data covering a new design sub-space from current learning data based on an active learning technique. In detail, the early-stage estimator 210 may augment learning data using a method of identifying a part difficult for the prediction model 21 to predict, performing new sampling to augment learning data, and then, repeating additional learning using the augmented learning data.

The optimization engine 300 may be provided to derive an optimization parameter for a design generated by inputting a simulation result obtained from the simulator 200 into at least one parameter optimization model 31 provided in advance.

The optimization engine 300 according to the present embodiment may evaluate whether the final simulation result estimated by the early-stage estimator 210 satisfies a target value corresponding to a predefined optimization objective.

At this time, the defined optimization objective may be changed at any time depending on a technical field in which a design is used. For example, in a case of a semiconductor industry, the predefined optimization objective may be an objective predefined by taking into account design objectives such as area optimization, wirelength optimization, power optimization, pin accessibility, and power-ground rail optimization. Here, the area optimization may be an objective to minimize a number of tracks while a width of a cell is fixed, i.e., optimize a space between transistors to minimize a cell height, or an objective to optimize a width while a height of the cell is fixed. The wirelength optimization may be an objective to improve pin accessibility by matching signal delay and transition time with a desired target value. The power optimization may be an objective to reduce power loss and maximize power efficiency by minimizing resistance-capacitance (RC) delay. The pin accessibility optimization may be an objective to set routing connections and reduce design complexity by adjusting pin locations for optimization.

When the final simulation result does not satisfy the target value, the optimization engine 300 according to the present embodiment may repeatedly perform the process of deriving and transmitting a new optimization parameter to the design generator 100 until the target value is satisfied.

The optimization engine 300 according to the present embodiment may be implemented as a multi-optimization engine that performs multiple functions.

First, the optimization engine 300 according to the present embodiment is a multi-optimization engine that pursues multiple optimization objectives, and may be implemented to pursue the multiple optimization objectives including at least two optimization objectives. To do so, the optimization engine 30 according to the present embodiment may find optimization points that satisfy the multiple optimization objectives, and derive optimization parameters by reflecting importance weights for respective optimization objectives according to the optimization points. The optimization points may be explored using Pareto frontier which is a boundary curve of a set of non-dominated solutions. By doing so, the optimization engine 300 may derive optimization parameters that pursue multiple optimization objectives such as fuel efficiency, a speed, and a production cost when a vehicle design is performed, and may derive optimization parameters that pursue multiple optimization objectives such as performance, power consumption, and heat generation when a semiconductor is designed.

In addition, the optimization engine 300 according to the present embodiment is a multi-optimization engine that generates a completely new design, and may also generate a new design using a generative artificial intelligence algorithm. By doing so, the optimization engine 300 according to the present embodiment may learn a design space to derive a solution that deviates from a distribution of the design space, or find a new variable that was not considered in an existing design and reflect the found new variable in optimization, rather than modifying a given design. For example, the optimization engine 300 according to the present embodiment may derive an optimization parameter according to an influence of a color on aerodynamics when a vehicle body is designed. In detail, the optimization engine 300 according to the present embodiment may analyze a degree of an influence of a vehicle color on aerodynamics using generative artificial intelligence, like a case in which, when a color of the vehicle is designed to be white, the white color reflects sunlight, and a temperature is changed by the reflection of the sunlight, which causes air density to be changed together. By doing so, an element that was not considered by a previous designer may be newly proposed. For example, the optimization engine 300 according to the present embodiment may automatically optimize and generate materials and structures when a semiconductor circuit is designed. In detail, the optimization engine 300 according to the present embodiment may automatically generate a structure capable of improving performance by exploring new material combinations or transistor arrangements using generative artificial intelligence, and discover and propose micro-patterns that were not considered by a previous designer.

In addition, the optimization engine 300 according to the present embodiment is a multi-optimization engine that performs a recommendation function, and may output and provide a combination of parameters having probabilistically good results in a form of options to a user based on a derived optimization parameter. When the user selects at least one of the output options, the optimization engine 300 according to the present embodiment may output and provide, to the user, additional options including derivative design information from the selected at least one option. In addition, when the user selects an option, the optimization engine 300 according to the present embodiment may provide additional information for respective options to the user by displaying differences in expected results between the respective options.

The optimization engine 300 according to the present embodiment may be driven in parallel.

In detail, the optimization engine 300 according to the present embodiment may derive an optimization parameter for each of a plurality of designs in parallel.

Meanwhile, when a design space region is explored, a parameter set that needs to be explored first may not be known. Thus, there may be a problem such that a design having a better performance is evaluated late.

Thus, the optimization engine 300 according to the present embodiment may determine priorities for respective designs and be driven in parallel according to the priorities. In detail, the optimization engine 300 according to the present embodiment may determine priorities for a plurality of designs based on optimization parameters for the plurality of designs, respectively, and dynamically allocate resources for deriving optimization parameters according to the priorities. That is, the optimization engine 300 according to the present embodiment may set priorities to explore parameters or new design sub-spaces that are to have good results among the plurality of designs.

The optimization engine 300 according to the present embodiment may monitor computational resources in real time and dynamically optimize resource allocation using a predefined resource allocation and scheduling algorithm.

The optimization engine 300 according to the present embodiment may dynamically optimize the resource allocation according to the priorities. In detail, when a high-priority design is newly found while parameter optimization derivation is being performed, the optimization engine 300 according to the present embodiment may dynamically optimize the resource allocation. By doing so, optimization of critical designs may be performed first, and thus, design optimization time may be shortened, and a hardware cost may be reduced by efficiently distributing the computational resources.

Hereinafter, sub-components of the optimization engine 300 configured to derive an optimization parameter from a parameter optimization model are described. The optimization engine 300 according to the present embodiment may include a feature extractor 310, an optimization model selector 330, and an optimizer 350, as illustrated in FIG. 2.

First, the feature extractor 310 may extract key features from a simulation result obtained from the simulator 200 according to an optimization objective and preprocess the extracted key feature to be processed by a parameter optimization model.

In detail, as illustrated in FIG. 2, the feature extractor 310 according to the present embodiment may receive an input of design data and domain features and extract key features, and may extract key features based on a result of analyzing a pattern of existing data.

In detail, the feature extractor 310 according to the present embodiment may first analyze a data type of input data. The feature extractor 310 according to the present embodiment may automatically analyze the input data to distinguish between data types such as a continuous data type and a discrete data type. In addition, the feature extractor 310 according to the present embodiment may determine whether to apply transformation such as normalization or log transformation by identifying a scale range of the input data. This may be a preprocessing for evaluating importance of each variable.

When the data types of the input data are distinguished, the feature extractor 310 according to the present embodiment may evaluate importance of features for each data type. In detail, the feature extractor 310 according to the present embodiment may evaluate variable importance, i.e., feature importance by utilizing statistical correlation analysis and feature selection techniques.

Here, a technique of analyzing the most appropriate correlation through pattern matching, e.g., Pearson's technique, Spearman's technique, Mutual Information technique, or the like may be applied to the statistical correlation. Feature selection techniques are techniques for identifying important variables, and may include a lasso technique, Shapley additive explanation (SHAP) technique, recursive feature elimination (RFE) technique, or the like.

The feature extractor 310 according to the present embodiment may perform normalization and transformation on corresponding data after evaluating the feature importance. Accordingly, as the feature importance is quantified by the feature extractor 310 according to the present embodiment, an optimal combination of input variables to be applied to training of the parameter optimization model 31 may be determined.

On the other hand, in such fields as quantum computing and neuro-science/engineering, there may be cases in which key features to be used for simulations need to be searched for directly due to absence of existing data or lack of expertise.

To do so, the feature extractor 310 according to the present embodiment may search for key features having a high impact on an optimization objective while repeating trial errors based on reinforcement learning. In detail, the feature extractor 310 according to the present embodiment may determine an optimal combination of key features by defining, as an action, determination about whether to add a feature, among all possible features, to key features while maximizing a reward.

Meanwhile, the optimization model selector 330 may select at least one parameter optimization model 31 configured to derive an optimization parameter according to an optimization objective and key features extracted from the feature extractor 310.

The optimization model selector 330 according to the present embodiment may be trained to select a parameter optimization model 31 that has a high probability of producing a good result value. Accordingly, an optimization result for a selected model or combination of selected models may be checked, and the optimization model selector 330 may be updated according to the optimization result. In detail, the optimization model selector 330 according to the present embodiment may be updated through feedback by checking an optimization result according to selection of a model. Thus, a parameter optimization model 31 having a highest probability of getting close to an optimization objective may be selected.

Hereinafter, an example of selecting a parameter optimization model 31 according to an optimization objective and key features is described.

First, the optimization model selector 330 according to the present embodiment may select different parameter optimization models 31 depending on whether the optimization objective is about precision or speed.

For example, when safety is important like in an aviation or medicine field, precise optimization is needed. Thus, a model with good performance when optimization is performed needs to be selected even when time is consumed. In this case, the optimization model selector 330 according to the present embodiment may select a parameter optimization model 31 based on a Bayesian algorithm.

On the other hand, in fields where real-time decision-making or production optimization is needed, an optimization parameter needs to be derived quickly. Thus, a model that gives a priority to a speed needs to be selected. In this case, the optimization model selector 330 according to the present embodiment may select a parameter optimization model 31 based on a greedy search algorithm.

In addition, based on the complexity of a problem, the optimization model selector 330 according to the present embodiment may select a parameter optimization model 31 based on reinforcement learning when the complexity of the problem is at a high level, and select a parameter optimization model 31 based on a gradient descent algorithm when the complexity of the problem is at a low level like linearity.

In addition, based on continuity of key features, the optimization model selector 330 according to the present embodiment may select a parameter optimization model 31 based on a genetic algorithm in a case of discrete continuity, and may select a parameter optimization model 31 based on a Bayesian algorithm in the case of continuous continuity.

In addition, based on a simulation execution speed, the optimization model selector 330 according to the present embodiment may select a parameter optimization model 31 based on a multi-fidelity optimization algorithm when consumption of a high cost is acceptable, and select a parameter optimization model 31 based on a random search algorithm when a low cost is needed.

In addition, based on a size of an exploration space, the optimization model selector 330 according to the present embodiment may select a parameter optimization model 31 based on a simulated annealing algorithm when a local search is needed, and may select a parameter optimization model 31 based on an evolutionary algorithm when a global search is needed.

Meanwhile, the optimization model selector 330 according to the present embodiment may select a parameter optimization model 31 based on multiple optimization algorithms rather than a single optimization algorithm.

In detail, the optimization model selector 330 according to the present embodiment may automatically explore combinations and sequences of parameter optimization models 31 according to characteristics of an optimization problem. For example, the optimization model selector 330 according to the present embodiment may perform a rough search in an initial stage by selecting a parameter optimization model 31 based on the Bayesian algorithm, then perform a global search in an intermediate stage by selecting a parameter optimization model 31 based on a genetic algorithm, and thereafter, perform fine-tuning in a final stage by selecting a parameter optimization model 31 based on a gradient descent algorithm.

Meanwhile, selecting a parameter optimization model 31 by the optimization model selector 330 may indicate that at least one parameter optimization model 31 of which training has been completed is selected, or training is to be executed on a selected parameter optimization model 31 after the parameter optimization model 31 is selected.

Hereinafter, a training process of a parameter optimization model 31 is described. Since a training process may be performed by at least one module in the optimization engine 300, the training process is described as a training process in the optimization engine 300 for convenience of description.

First, the optimization engine 300 according to the present embodiment may train a parameter optimization model 31 using learning data provided in advance. To do so, the optimization engine 300 according to the present embodiment may augment the learning data to cover a target design area of an optimization parameter. In detail, the optimization engine 300 according to the present embodiment may identify a design area covered by current learning data and augment the learning data to secure learning data for a target design area based on the identified one. Since the augmentation of the learning data is identical or similar to the augmentation performed by the early-stage estimator 210, a detailed description thereof is not provided here.

The optimization engine 300 according to the present embodiment may generate a parameter optimization model 31 according to at least one learning method using the learning data described above.

First, the optimization engine 300 according to the present embodiment may generate a parameter optimization model 31 according to a reinforcement learning method. At this time, an optimization parameter derived by the optimization engine 300 may be derived by adjusting a particular parameter value which represents an action to maximize a reward. For example, when precision is a predefined optimization objective, the optimization parameter may refer to a parameter derived according to an action of adjusting a parameter value related to the precision to achieve the optimization objective.

The optimized parameter derived from performance of the action is transmitted to the design generator 100. Then, the design generator 100 may perform an optimization process using a feedback method of modifying a design, evaluating whether a design obtained as a result of the modifying has precision improved over the design before the changing using a reward function, and performing an action of adjusting a parameter value again according to the reward function.

An example of deriving an optimization parameter through the parameter optimization model 31 based on reinforcement learning according to an embodiment of the present disclosure has been described above. However, the present disclosure is not limited thereto, and other than the reinforcement learning, any optimization technique capable of optimizing a parameter according to feedback may be applied to the parameter optimization model 31 in the present disclosure. For example, a method such as optimization using learning like a neural network optimization, Bayesian optimization, etc., and gradient-based optimization which performs optimization using a differentiable objective function may be used.

Meanwhile, the optimization engine 300 according to the present embodiment may generate a parameter optimization model by performing transfer learning through determination of a similarity between design domains with respect to a parameter optimization model 31 provided in advance.

In detail, the optimization engine 300 according to the present embodiment may generate a parameter optimization model 31 which is domain-adaptive, by performing transfer learning to enable optimization for a similar domain in a corresponding field through a parameter optimization model 31 in another field. At this time, the optimization engine 300 according to the present embodiment may identify a similar domain by taking into account at least one from among a data-based similarity using statistical distribution of key features of simulation result data, an optimization objective similarity, a design variable similarity of design data, and an optimization algorithm similarity.

In addition, the optimization engine 300 according to the present embodiment may generate a parameter optimization model 31 by performing fine tuning to fit a domain of input data. For example, to generate a second parameter optimization model using both images and vectors as input data from a first parameter optimization model using only images as input data, the optimization engine 300 according to the present embodiment may directly employ the first parameter optimization model, and add a layer for processing vector input data to generate a second parameter optimization model that is fine-tuned to fit a domain of input data.

The optimization engine 300 according to the present embodiment may train a parameter optimization model 31 based on human design learning data generated by an expert. That is, by using learning data in which parameters of a human design are set as correct answers, the optimization engine 300 according to the present embodiment may train the parameter optimization model 31 so that optimization parameters output from the parameter optimization model 31 pursue the parameters of the human design. The optimization engine 300 including the parameter optimization model 31 trained as described above may learn knowledge of an expert by utilizing previous data designed by the expert. At this time, the optimization engine 300 according to the present embodiment may train the parameter optimization model 31 according to learning methods such as supervised learning, behavior cloning, imitation learning, etc. The above-described learning methods are only examples and the present disclosure is not limited thereto.

The optimizer 350 may input key features preprocessed by the feature extractor 310 into at least one parameter optimization model to derive optimization parameters. In addition, the optimizer 350 according to the present embodiment may also input key features preprocessed by the feature extractor 310 into a parameter optimization model selected by the optimization model selector 330 to derive optimization parameters.

As described above, the device 10 according to the present embodiment may detect at least one event preset from a preliminary simulation result by the early-stage estimator 210 and transmit the detected event to the optimization engine 300 to derive an optimization parameter that pursues an optimization objective corresponding to the detected preset event. In detail, the device 10 according to the present embodiment may detect in advance an area with a high possibility of occurrence of the event by exploring a structure similar to a pattern that occurred in a past design, and transmit a result of the detection to the optimization engine 300 to resolve an event corresponding to a result of the detection.

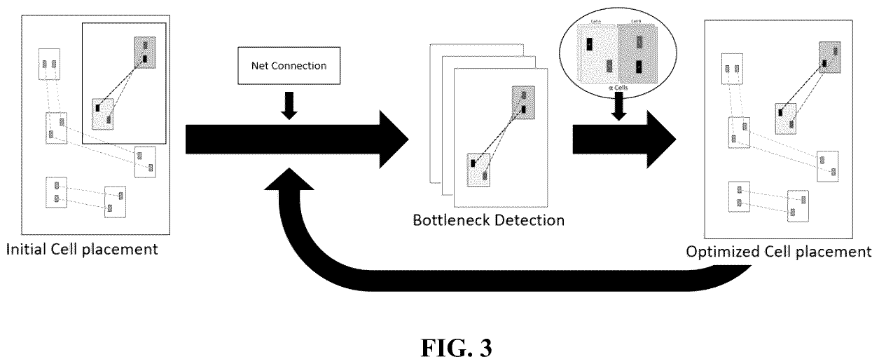

Hereinafter, referring to FIG. 3, an application example in which the device 10 according to the present embodiment is applied to a semiconductor industry is described. FIG. 3 is a diagram illustrating an example of a case in which a location in which a cell is placed is optimized when the device 10 according to the present embodiment generates a semiconductor chip design.

For example, when a design is applied to the semiconductor industry, the device 10 according to the present embodiment may detect events including a congestion hotspot event, a detour path event, a cell overlap event, a critical timing area event, a design rule violation event, a voltage drop (intermediate resistance (IR) drop) & power hotspot event, a signal integrity (crosstalk) event, etc. in advance by the early-stage estimator 210.

Here, the congestion hotspot event may refer to a case in which a routing track usage rate in a particular area is a threshold or higher (e.g., 70%). The detour path event may refer to a case in which a routing path is inefficiently long, such as a case in which a ratio of an actual wirelength to a half-perimeter wire length (HPWL) is 1.5 or higher. The cell overlap event refers to a case in which overlapping is present even after legalization, and may be an event defined due to a possibility of occurrence of a cell density problem in a placement stage. The critical timing area event is an item needed to evaluate an impact of a routing on a timing critical path, and may be detected through analysis of areas in which timing slack is low (e.g., −0.2 ns or less). The design rule violation (DRV) event is an item for identifying routing zones with a high possibility of minimum spacing violations or design rule checks (DRC) violations. For example, when a possibility of spacing violations corresponds to a preset threshold value or higher, this may be detected as a DRV. The voltage drop and power hotspot event may be an event for detecting zones with a high possibility of a severe voltage drop (IR drop) due to concentration of power consumption in a particular area. The signal integrity event may be an event for detecting a section with a high possibility of signal interference (crosstalk) between nets.

Meanwhile, the device 10 according to the present embodiment may evaluate a possibility of occurrence of the events described above according to quantitative evaluation criteria based on pattern matching by the early-stage estimator 210. In detail, the device 10 according to the present embodiment may evaluate a possibility of occurrence of an event based on a probability through the prediction model 21. For example, when a probability of occurrence of congestion in a particular routing structure is 85%, the device 10 according to the present embodiment may respond in advance at a cell placement stage. When a risk of occurrence of timing violation in a timing path including a particular net is 90%, this may be predicted as a possibility of occurrence of a problem at a routing stage. Additionally, when a probability of occurrence of a signal integrity problem in a particular area with dense routing is 80% or greater, it may be predicted that pin rearrangement or routing adjustment is needed.

The detailed description above is only an example in a semiconductor industry provided for convenience of description, and the present disclosure is not necessarily limited thereto. It is obvious that items needed to evaluate simulation results in each industry may be changed.

When a problem pattern of a semiconductor chip is analyzed in advance through the preliminary simulation result described above, the device 10 according to the present embodiment may perform an optimization process of performing optimal cell placement through the optimization engine 300.

For example, as shown in FIG. 3, through a preliminary simulation result, a location where congestion or a design rule violation (DRV) is expected after cell placement may be tracked by pattern matching. In relation to this, the optimization engine 300 may optimize a parameter for a position of a cell in the location which the congestion or design rule violation (DRV) is detected. In addition, an optimization parameter derived therefrom may be transmitted to the design generator 100.

For example, when an area with high congestion is detected through a preliminary simulation result, the optimization engine 300 may optimize a parameter to select a pin layout with a less routing tangle. In addition, when a setup/hold violation occurs, the optimization engine 300 may optimize a critical path routing by deriving a parameter for performing replacement by a layout in which a routing length is minimized by reducing a pin-to-pin distance. In addition, when a routing is detected as having a too long detour path through a preliminary simulation result, the optimization engine 300 may perform optimization by deriving a parameter to perform routing in a shortest path using a method of minimizing a delay by adjusting a pin position. Additionally, when an area with a high voltage drop is detected through a preliminary simulation result, the optimization engine 300 may perform voltage drop optimization by deriving a parameter for performing replacement by a layout in which a power grid (VDD/VSS) connection is efficient. In addition, when a signal integrity with a severe signal interference between adjacent nets is detected through a preliminary simulation result, the optimization engine 300 may perform optimization for signal integrity by deriving a parameter for performing replacement by a layout in which a routing path with favorable electrical characteristics is provided.

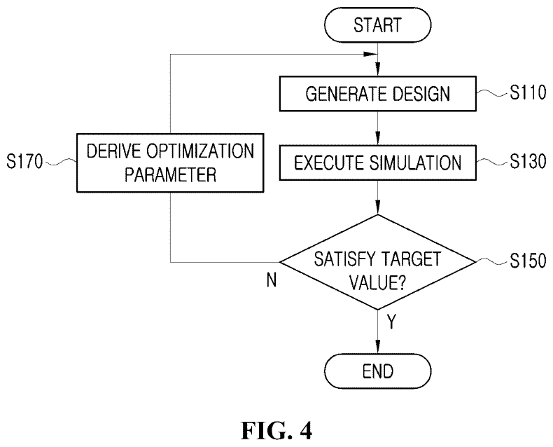

FIG. 4 is a flowchart for explaining a design generation method according to an embodiment of the present disclosure. Since the design generation method according to an embodiment of the present disclosure is performed in a configuration substantially identical to that of the design generation device 10 illustrated in FIGS. 1 and 2, same reference numerals are given to same components as those of the design generation device 10 illustrated in FIGS. 1 and 2, and a description thereof is not repeatedly provided here.

As the design generation method according to the present embodiment, when design data is input, the design generator 100 generates at least one design (S110).

Then, the simulator 200 simulates the generated design (S130).

The simulating (S130) may include estimating, by the early-stage estimator 210, a final simulation result from an early simulation result of the generated design to establish preliminary design optimization.

In addition, the simulating (S130) may further include using the prediction model 21 based on machine learning, the prediction model 21 being trained to predict a final simulation result using a simulation result as learning data, and updating the prediction model 21 based on a result of comparing a final result of simulation performed by the simulator to the predicted final simulation result.

Then, the optimization engine 300 performs optimization (S170) of deriving an optimization parameter for the generated design by inputting an evaluation result obtained from the simulator 200 into a parameter optimization model 31 provided in advance.

The optimizing (S170) may include evaluating whether the final simulation result predicted by the early-stage estimator 210 satisfies a target value corresponding to a predefined optimization objective (S150).

The optimizing (S170) may include, when the predicted final simulation result does not satisfy the target value, repeatedly performing a process of deriving and transmitting a new optimization parameter to the design generator 100 until the predicted final simulation result satisfies the target value.

In addition, the design generation method according to the present embodiment may further include modifying, by the design generator 100, the generated design according to the optimization parameter derived in the deriving (S170) of the optimization parameter.

The design generation method in the present disclosure may be implemented in a form of program instructions that may be executed through various computer components and recorded in a computer-readable recording medium. The computer-readable media may include program commands, data files and data structures solely or in combination.

The program commands recorded on the computer-readable recording medium may be specially designed and configured for the present disclosure or may be known and available to those skilled in the art in the computer software field.

For example, the computer-readable recording media include magnetic media such as hard disks, floppy disks, and magnetic media such as a magnetic tape, optical media such as CD-ROMs and DVDs, magneto-optical media such as floptical disks, and hardware devices specifically configured to store and execute program commands, such as ROM, RAM, and flash memory.

Examples of program code include both machine language codes produced by a compiler, and a high-level language code that can be used by an interpreter or similar tools to be executed by a computer. The above hardware device may be configured to operate as one or more software modules to perform processing according to the present disclosure, and vice versa.

Although various embodiments of the present disclosure are illustrated and described, the present disclosure is not limited to the particular embodiments described above and various changes and modifications thereof may be made by those skilled in the art without departing from the essence of the disclosure as claimed in the claims. Such changes and modifications should not be understood as being separate from the technical idea or viewpoint of the present disclosure.

### EXPLANATION OF REFERENCE NUMERALS

10: design generation device
100: design generator
200: simulator
210: early-stage estimator
300: optimization engine
310: feature extractor
330: optimization model selector
350: optimizer

1. A design generation device comprising:
a design generator configured to generate at least one design from design data;
a simulator configured to simulate the at least one design; and
an optimization engine configured to derive an optimization parameter for the at least one design by inputting a simulation result obtained from the simulator into at least one parameter optimization model provided in advance,
wherein the design generator modifies the at least one design according to the optimization parameter.

2. The design generation device of claim 1, wherein the simulator comprises an early-stage estimator configured to estimate a final simulation result from a preliminary simulation result obtained from the simulator with respect to the at least one design and establish preliminary design optimization.

3. The design generation device of claim 2, wherein the early-stage estimator comprises a prediction model trained to estimate the final simulation result using the simulation result as learning data.

4. The design generation device of claim 3, wherein the early-stage estimator identifies a design area covered by the learning data by inputting the learning data into a pre-provided coverage check model, and trains the prediction model by augmenting the learning data to secure the learning data for a new design sub-space according to the design area.

5. The design generation device of claim 2, wherein the optimization engine evaluates whether the final simulation result estimated by the early-stage estimator satisfies a target value corresponding to a predefined optimization objective, and when the target value is not satisfied, repeatedly performs a process of deriving and transmitting a new optimization parameter to the design generator until the target value is satisfied.

6. The design generation device of claim 1, wherein the optimization engine comprises:
a feature extractor configured to extract a key feature from the simulation result according to an optimization objective and preprocess the key feature; and
an optimizer configured to input the key feature into the at least one parameter optimization model to derive the optimization parameter.

7. The design generation device of claim 6, wherein the optimization engine further comprises an optimization model selector configured to select the at least one parameter optimization model configured to derive the optimization parameter according to the optimization objective and the key feature extracted from the feature extractor.

8. The design generation device of claim 1, wherein the optimization engine generates a domain-adaptive parameter optimization model by performing transfer learning through determination of a similarity between design domains for the at least one parameter optimization model provided in advance.

9. The design generation device of claim 1, wherein, when a predefined optimization objective comprises multiple optimization objectives (multi-objectives) comprising at least two optimization objectives, the optimization engine finds an optimization point satisfying the multiple optimization objectives and derives the optimization parameter by reflecting an importance weight for each of the multiple optimization objectives according to the optimization point.

10. The design generation device of claim 1, wherein the optimization engine derives optimization parameters for a plurality of designs based on parallel processing, determines priorities for the plurality of designs based on the optimization parameters for the plurality of designs, respectively, and dynamically allocates resources for deriving the optimization parameters according to the priorities.

11. The design generation device of claim 1, wherein the optimization engine trains the at least one parameter optimization model based on learning data of a human design generated by an expert and pursues parameters of the human design.

12. A design generation method comprising:
generating, by a design generator, at least one design from design data;
simulating, by a simulator, the at least one design;
deriving, by an optimization engine, an optimization parameter for the at least one design by inputting a simulation result obtained from the simulator into at least one parameter optimization model provided in advance; and
modifying, by the design generator, the at least one design according to the optimization parameter.

13. The design generation method of claim 12, wherein the simulating comprises estimating, by an early-stage estimator, a final simulation result from a preliminary simulation result with respect to the at least one design to establish a preliminary design optimization.

14. The design generation method of claim 13, wherein the early-stage estimator comprises a prediction model trained to predict the final simulation result using the simulation result as learning data.

15. The design generation method of claim 13, wherein the deriving the optimization parameter comprises:
evaluating whether the final simulation result estimated by the early-stage estimator satisfies a target value corresponding to a predefined optimization objective, and
when the target value is not satisfied, repeatedly performing a process of deriving and transmitting a new optimization parameter to the design generator until the target value is satisfied.
